(19) United States
(12) Patent Application Publication
(10) Pub. No.: US 2017/0212558 A1
(43) Pub. Date: Jul. 27, 2017

(54) CONTOURED INTERLOCK FOR THIN WALL SECTIONS IN CERAMIC

(71) Applicant: Apple Inc., Cupertino, CA (US)

(72) Inventors: Colin M. ELY, Sunnyvale, CA (US); Adam T. CLAVELLE, San Francisco, CA (US); Steven P. CARDINALI, Campbell, CA (US)

(21) Appl. No.: 15/004,768

(22) Filed: Jan. 22, 2016

(51) Int. Cl. G06F 1/18; H05K 5/02; H05K 5/00; F16B 37/12; G06F 1/16

(52) U.S. Cl. CPC G06F 1/183; F16B 37/125; G06F 1/1688; G06F 1/163; H05K 5/0017; H05K 5/0217

(57) ABSTRACT

This application relates to an insert nut for a housing of a computing device. The insert nut can include a threaded interior surface for receiving a screw, and a ribbed exterior surface for receiving an adhesive between ribs of the ribbed exterior surface. At least one of the ribs can include at least one notch that allows for an adhesive to flow between ribs. When the insert nut is pressed into an adhesive filled cavity, the adhesive can flow over the notch and between the ribs of the insert nut. Thereafter, the adhesive can be cured in order to secure the insert nut to the housing. This arrangement allows for screws to be secured into the insert nut rather than directly into the housing, thereby reducing cracks that can otherwise form in the housing.

### FIELD

The described embodiments relate generally to insert nuts for computing device housings. More particularly, the present embodiments relate to insert nuts that can be glued into ceramic housings so that screws can be secured into the insert nut rather than directly into the ceramic housings.

### BACKGROUND

A housing of a computing device can be made from a variety of materials for protecting a variety of electrical components. Certain materials can make assembly of the computing device more difficult than others because of the fragility of the materials. For example, some materials may be prone to cracking during drilling of the materials and assembly of the computing device. As a result, materials that have cracked may be discarded, thereby raising the cost of manufacturing the computing devices made from such materials. Furthermore, even when the computing device is successfully manufactured, cracks may still form in the housing of the computing device during normal use of the computing device.

### SUMMARY

This paper describes various embodiments that relate to insert nuts for computing device housings. In one embodiment, a method for attaching a nut to a housing of a computing device is set forth. The nut can include a ribbed exterior with at least one notch and a threaded interior. The method can include the steps of depositing an adhesive into a cavity of the housing, and depressing the nut into the cavity of the housing such that the adhesive flows over the at least one notch. The method can further include causing the adhesive to move over the at least one notch and between ribs of the threaded exterior to create a bond between the nut and the housing.

In another embodiment, an insert nut is set forth. The insert nut can include a body having a threaded interior and a ribbed exterior. The ribbed exterior can include ribs and at least one notch, and the at least one notch can act as a fluid pathway between the ribs. Furthermore, the ribbed exterior can include multiple notches that are staggered about a periphery the ribbed exterior.

In yet other embodiments, a computing device is set forth. The computing device can include a housing that includes at least one side wall having a cavity. Additionally, the computing device can include an insert nut disposed within the cavity. The insert nut can include a threaded interior and a ribbed exterior. The ribbed exterior can include at least one notch in a rib of the ribbed exterior. Furthermore, the computing device can include a bonding material disposed between the at least one notch and a wall of the cavity. In some embodiments, the housing can be formed from a ceramic material such as zirconia. The computing device can also include an electrical component and a screw fastened to the insert nut through a portion of the electrical component to secure the electrical component to the housing.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements.

FIGS. 1A and 1B illustrate perspective views of a computing device that can incorporate the insert nut discussed herein.

FIGS. 2A and 2B illustrate perspective views of a device housing that can incorporate the insert nut discussed herein.

FIGS. 3A and 3B illustrate perspective views of an embodiment of the insert nut discussed herein.

FIGS. 4A and 4B illustrate perspective views of an embodiment of the insert nut having a flat surface as discussed herein.

FIGS. 5A and 5B illustrate perspective views of an embodiment of the insert nut having multiple threaded apertures as discussed herein.

FIG. 6 illustrates a cross-sectional view of the insert nut disposed within a cavity of a housing.

FIG. 7 illustrates a cross-sectional view of the insert nut disposed within a cavity having cutout regions for additional adhesive to reside and adhere to the insert nut.

FIG. 8 illustrates a method for assembling a device housing to incorporate the insert nut.

FIG. 9 illustrates a method for manufacturing the insert nut discussed herein.

### DETAILED DESCRIPTION

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

The embodiments set forth herein relate to insert nuts for a housing of a computing device. Because the housing of computing device can be made from certain materials that fracture under stress, it can be beneficial to use extra precautions when assembling the computing device. For example, some components of the computing device can be screwed into the housing of the computing device, thereby creating added stresses on the computing device in areas where the components are screwed into the computing device. In order to protect against cracking caused by the added stresses, an insert nut can be attached to one or more surfaces of the housing. The insert nut can be set near areas of the housing where a component is to be screwed into the housing and there exists a thin wall near the area. In this way, fracturing can be prevented at the thin wall.

The insert nut can include a ribbed exterior surface and a threaded interior surface. The threaded interior surface can be used for securing a screw by allowing the screw to be secured by a force of friction between the screw and the threaded interior surface. The ribbed exterior surface can include a number of ribs that have an amount of space between the ribs suitable for receiving an adhesive between the ribs. One or more of the ribs can have one or more notches or cutouts that are on the same section of each rib, or different sections of each rib to create a staggered arrangement of notches. Additionally, in some embodiments, one or more ribs do not have a notch thereby preventing adhesive from flowing over the rib during assembly, as further discussed herein. For example, a rib on a distal end of the insert nut can be left un-milled or uncut so that the rib does not have a notch. Furthermore, an outer diameter of the rib on the distal end of the insert nut can have a diameter that is equal to, greater than, or less than a diameter of another rib on the insert nut. The ribs of the ribbed exterior surface can be formed over the entire perimeter of the insert nut or a partial perimeter of the insert nut. In this way, the exterior surface of the insert nut that does not include the ribs can remain flat or have some other surface texture. The insert nut can be shaped to fill a housing cavity that is to at least partially envelope a screw for securing a component to the housing. By not limiting the insert nut to a circular configuration, the arrangement of the insert nut in the housing can be made more versatile, allowing screws to be secured in places that might otherwise compromise the integrity of the housing.

The cavity for the insert nut can be customized in order to optimize the bonding between the adhesive, the cavity, and the insert nut. For example, portions of the cavity can be undercut or otherwise removed in order for a greater volume of adhesive to be received into the cavity. As a result, when the insert nut is pressed into the cavity and the adhesive, the adhesive can flow over the ribs and notches of the insert nut, as a well as into the undercut portions of the cavity. Surface contact of the adhesive with the cavity and insert nut can be maximized by varying the volume of adhesive used for each respective cavity and insert nut. Additionally, the viscosity for the adhesive can be varied in order to maximize or minimize flow of the adhesive over the notches, between the ribs, and/or into the undercuts of the cavity when applicable. During reworking of a device that incorporates the insert nut, a solvent can be used to remove the adhesive, and the insert nut can thereafter be removed and reused.

Assembly of a housing having the insert nut can be performed in a number of steps. The housing can first be drilled to form a cavity in the housing that is suitable for receiving the insert nut. Next, an amount of adhesive is dispensed into the cavity of the housing. The amount of adhesive can be any amount of adhesive that will ensure enough adhesive flows over at least a notch of the insert nut and/or between ribs of the insert nut. The insert nut can thereafter be pressed into the cavity and adhesive. As a result, the adhesive can flow over the ribbed exterior. Because the ribbed exterior surface includes notches, pressure from pressing the insert nut into the adhesive can cause the adhesive to flow between a cavity wall and the notch. Once some of the adhesive is over a portion of the notch, the adhesive can thereafter flow between ribs of the ribbed exterior surface. By flowing between the ribs, the adhesive will also bond regions of the cavity walls that are facing the areas between the ribs. When the adhesive is a curable adhesive, the adhesive can be at least partially cured after the insert nut has been pressed into the cavity and the adhesive. If another insert nut is to be placed into another cavity of the housing, the aforementioned steps can be repeated. Once all insert nuts have been placed into the housing and their respective adhesives have been at least partially cured, the housing can undergo a final bake where the temperature of the housing is raised in order to completely cure the adhesives in each cavity.

Manufacturing of the insert nut can be performed in a variety of ways. For example, the insert nut can be made from a bar made from stainless steel, or any other material suitable for acting as a nut for a screw. The bar can be set on a lathe for processing. For example, a computer numeric control (CNC) machine can be used to cut ribs into each section of the bar to create the ribbed exterior surface for the insert nut. The flat edges of the sections can be cut in order to create angled or curved edges on the distal ends of the sections. Notches in the ribs can thereafter be cutout from the ribs using a milling or other spindle tool. The sections can be further reduced on one or more sides in order to give each section a geometry that will allow it to fit into non-circular cavities. For example, the section or insert nut can be machined to have a flat exterior surface and a curved exterior surface, similar to a D-shaped geometry. Furthermore, the insert nut can be machined to have multiple flat exterior surfaces and one or more curved exterior surfaces. The insert nut can also be circular, oval, polygonal, or any other suitable shape. Dimensions of the insert nut can be one or more millimeters in outer diameter and one or more millimeters in inner diameter. However, the size of the insert nut can vary to be any size suitable for receiving a screw of a particular device housing.

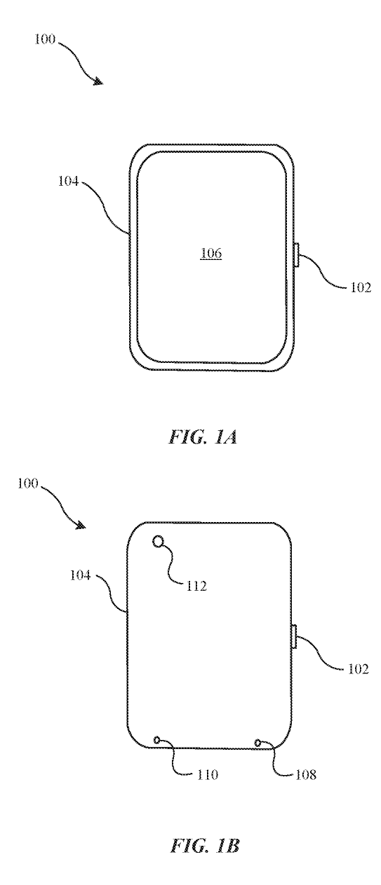

These and other embodiments are discussed below with reference to FIGS. 1A-9; however, those skilled in the art will readily appreciate that the detailed description given herein with respect to these figures is for explanatory purposes only and should not be construed as limiting.

FIG. 1A illustrates a front facing view of a computing device 100 that can incorporate one or more of the insert nuts discussed herein. The computing device 100 can be any type of computing device including, but not limited to, a watch, a laptop computer, a desktop computer, a display device, a tablet computer, a media player, a cellular phone, or any other device that can incorporate a component secured to a housing by a nut. The computing device 100 can include a housing 104 that supports a display 106 and at least one button 102 extending from the housing 104. The display 106 can extend over an opening in the housing 104 and cover electrical components within the housing 104. The button 102 can be attached to one or more electrical components within the housing 104, and can at least partially extend through one or more openings in a side of the housing 104. The electrical components and/or button 102 can be secured to the housing 104 using one or more insert nuts discussed herein. The insert nut can be disposed within a cavity of the housing 104 to minimize cracking of the housing 104. For example, the housing 104 can be made from a variety of materials including, but not limited to, ceramic, zirconia, glass, crystal, metal, plastic, and/or any other material that can be susceptible to cracking when under stress. In areas of the housing 104 where cracking may be more likely to occur, a cavity can be drilled into the housing 104 and an insert nut can be adhered within the cavity as further discussed herein. In this way, a screw does not necessarily need to be screwed directly into the housing 104 to secure a component to the housing 104, but rather the screw can be screwed into the insert nut to reduce cracking originating from an entry point of the screw.

FIG. 1B illustrates a rear facing view of the computing device 100. The computing device 100 can include a number of useful features such as a sensor 112, an audio device 110 such as a speaker and/or microphone, and/or a vent 108. Each of the sensor 112, the audio device 110, and the vent 108 can be secured to the housing 104 using the insert nut discussed herein. Because of the limited space within the housing 104, it can be useful to consolidate the number of screw locations to maximize the available space for additional components while also improving the structural integrity of the housing 104. The insert nut discussed herein accomplishes this by the ability of the insert nut to fit into a number of different surfaces on the housing 104, such as walls, corners, and edges. Furthermore, the insert nut can include openings for one or multiple screws to be secured into the insert nut. The insert nut can be circular or non-circular in shape in order to fit into certain areas of the housing 104 that may not be best suited for inserting a nut for a screw. For example, the insert nut can be D-shaped, and the flat part of the insert nut can be placed adjacent to a thin wall near an opening in the housing 104. This provides a more efficient use of space within the housing 104 in part by not limiting the nuts of the housing 104 to circular nuts.

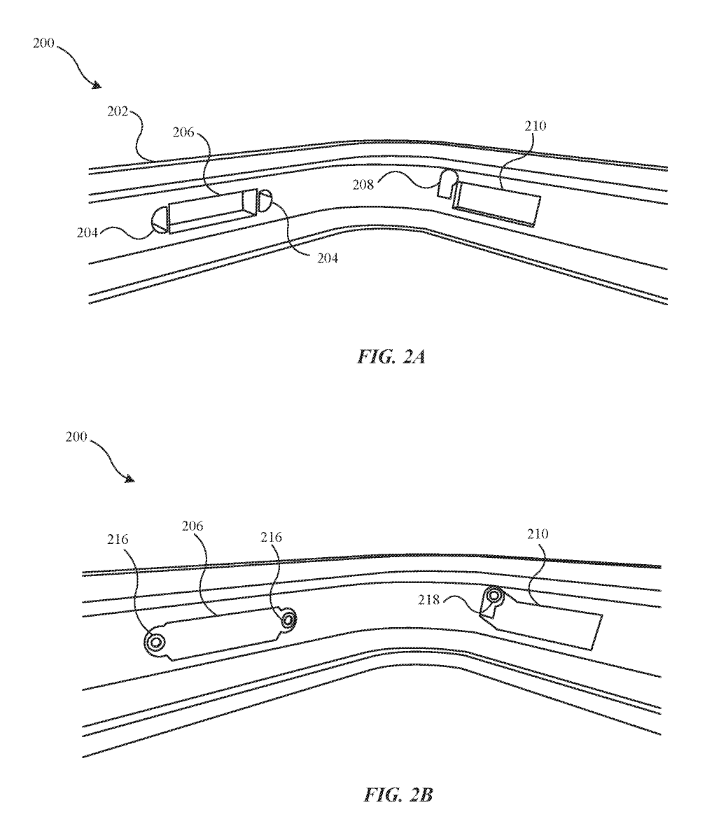

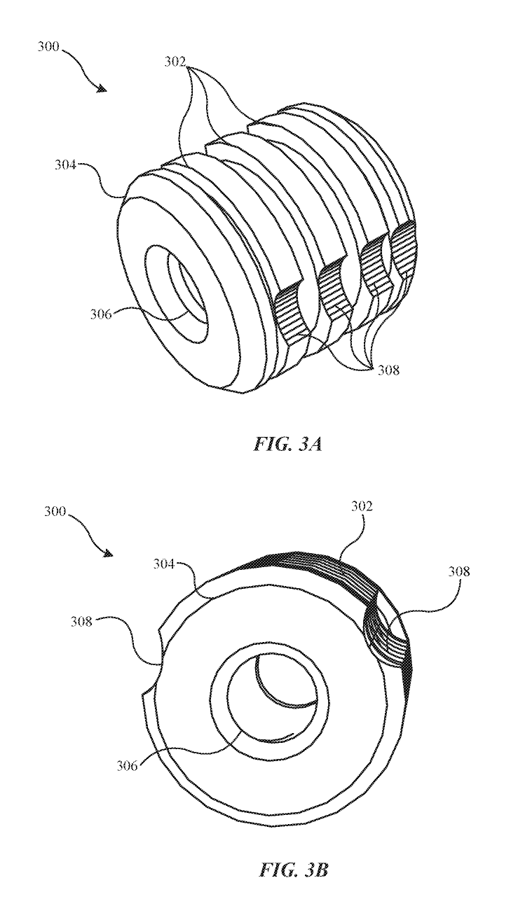

FIG. 2A illustrates a perspective view of a portion of a housing 200 for a computing device that can incorporate the insert nuts discussed herein. For example, the housing 200 can be for the computing device 100 discussed herein. The housing 200 can include multiple component cells 206 and 210 in which different components of computing device can reside. For example, the component cells 206 and 210 can incorporate the sensor 112, audio device 110, vent 108, button 102, and/or any other component suitable for connecting to a computing device. For example, when the housing 200 is incorporated into an assembled computing device, different components of the computing device can at least partially extend into the component cells 206 and 210. In order to ensure that the components will be adequately secured to the housing, one or more cavities such as cavities 204 and 208 can be formed in the housing 200. For example, when the housing 200 is made from a ceramic material such as zirconia, the cavities 204 and 208 can be drilled into the housing 200. The cavities 204 and 208 can thereafter be occupied by an insert nut, which can be secured into the cavities 204 and 208 by an adhesive. The insert nut can allow a screw to be drilled into the housing 200 without risk of cracking the housing 200. For example, the portion of the housing 200 between cavity 204 and component cell 206 can be prone to cracking when excess pressure is applied to the housing 200 between the cavity 204 and the component cell 206. Additionally, the opening 210 can be prone to cracking when a component is attached within the opening 210, unless an insert nut is disposed within the cavity 208 to secure a component to the housing 200.

FIG. 2B illustrates a perspective view of the housing 200 having insert nuts 216 and 218 disposed within different portions of the housing 200. For example, the insert nuts 216 can be disposed adjacent to the sides of the component cell 206. The insert nuts 216 can include a flat side and a curved side in order to allow the insert nuts 216 to fit into areas of the housing 200 that may not be suitable for a nut that is entirely round. The insert nut 218 can include a threaded region for receiving a screw and a securing portion on an outside portion of the insert nut 218 for receiving adhesive. By incorporating the securing portion in the insert nut 218, the insert nut 218 can be more tightly secured into various areas of the housing 200 such as corners and areas adjacent to thin walls. In some embodiments, an insert nut can be laterally disposed within an interior edge of an opening in the housing 200 to secure a component to the housing 200. Furthermore, by incorporating the insert nuts 216 and 218 near component cells 206 and 208, less cracking will occur in comparison to when screws are drilled directly into the housing 200. As a result, fractures that would otherwise occur around the component cells 206 and 208 will not occur.

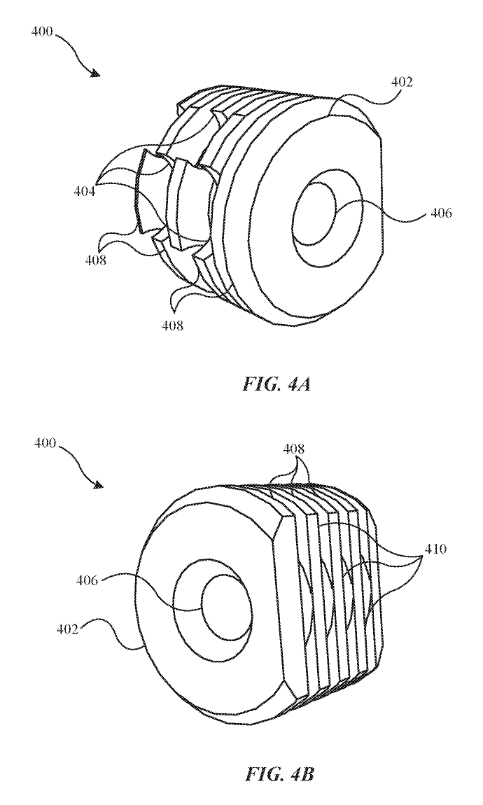

FIGS. 3A and 3B illustrate perspective views of an insert nut 300 as discussed herein. The insert nut 300 can include a threaded interior 306 that is suitable for receiving a screw. The threads of the threaded interior 306 can extend through the entire threaded interior 306 or partially through the threaded interior 306. The insert nut 300 can also include ribs 302 on an exterior surface of the insert nut 300. The insert nut 300 can include any number of ribs 302 and be separated by any suitable amount of space that will allow a fluid to flow between the ribs. For example, when the insert nut 300 is inserted into a cavity that includes an adhesive, the adhesive can flow between the ribs 302 in order to secure the insert nut 300 into the cavity. The adhesive can flow over notches 308 that are featured on one or more of the ribs 302. The notches 308 allow for the adhesive to initially flow around the exterior of the insert nut 300 and thereafter enter areas between the ribs 302. The adhesive can thereafter be cured in order to secure the insert nut 300 within the cavity.

FIGS. 4A and 4B illustrate perspective views of an insert nut 400 with at least one flat side. The insert nut 400 can include ribs 408 that make up a portion of an exterior of the insert nut 400. The insert nut can also include a threaded interior 406 extending through a longitudinal axis of the insert nut 400. The threaded interior 406 can be suitable for a screw to be tightened and secured into. The insert nut 400 can also include a number of staggered notches 404 cut out or otherwise formed in each of the ribs 408. The notches 404 can be arranged such that at least one notch 404 in one rib 408 is not formed on the same location as a notch 404 in an adjacent rib 408. In other words, at least some of the notches 404 can have a staggered arrangement relative to a longitudinal axis of the insert nut 400. In this way, when the insert nut 400 is pressed into a cavity that has some amount of adhesive, the adhesive can be forced to flow over a notch 404 and between ribs 408, before flowing over another notch 404. This arrangement ensures that the adhesive will spread out over the exterior of the insert nut 400 in different directions.

FIG. 4B illustrates a perspective view of the insert nut 400, which illustrates flat surfaces 410 that can be formed into a side of the insert nut 400. The flat surfaces 410 can be designed to align with a surface of a cavity in which the insert nut 400 can be disposed within. For example, when the cavity includes a wall that is round and a wall that is flat, a perimeter of the insert nut 400 will resemble the walls of the cavity. A rib 408 at an end 402 of the insert nut 400 can be left without a notch 404, thereby preventing any adhesive from flowing past the rib 408 at the end 402. As a result, adhesive flowing over the staggered notches 404 and between the ribs 408 will not flow past the rib 408 at the end 402. It should be noted that the insert nut 400 and the insert nut 300 can be combined in any manner to create variations of each respective insert nut. For example, the insert nut 300 can include staggered notches as described with respect to FIGS. 4A and 4B. Additionally, the insert nut 400 can include multiple flat surfaces 410 arranged in different orientations about a perimeter of the insert nut 400.

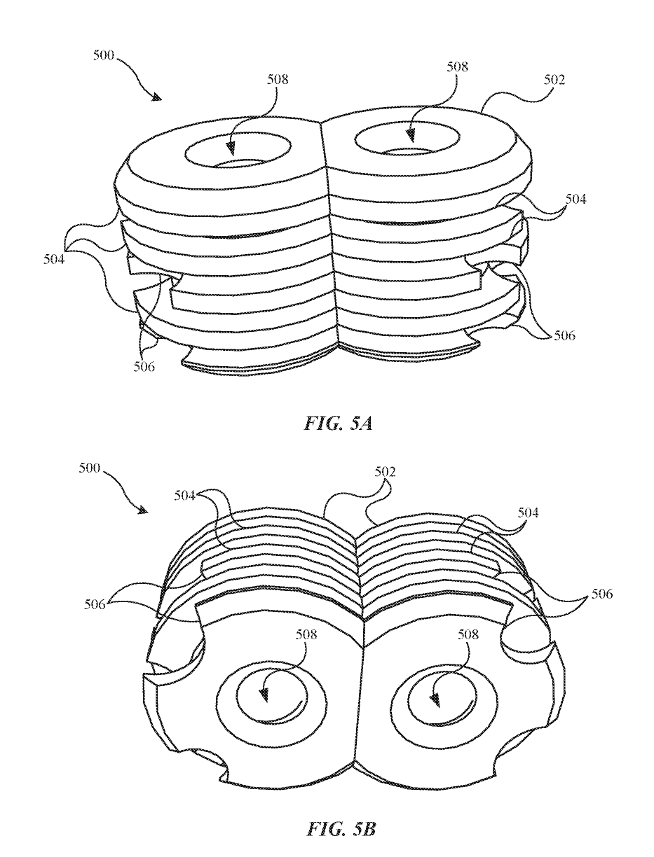

FIGS. 5A and 5B illustrate perspective views of an insert nut 500 having multiple threaded apertures 508. By incorporating multiple threaded apertures 508 into the insert nut 500, one or more components can be more securely fastened to a housing in which the insert nut 500 can be incorporated. The insert nut 500 can include a number ribs 504, between which adhesive can flow when securing the insert nut to the housing. The ribs 504 can include staggered or non-staggered notches 506 to promote the flow of adhesive over adjacent ribs 504. When pressed into adhesive disposed within a cavity of a housing, the adhesive can flow between ribs 504 and partially or fully around the perimeter of the insert nut 500. Although the insert nut 500 is illustrated as having concave sides, it should be noted that the sides of the insert nut 500 can be flat, convex, or any combination thereof.

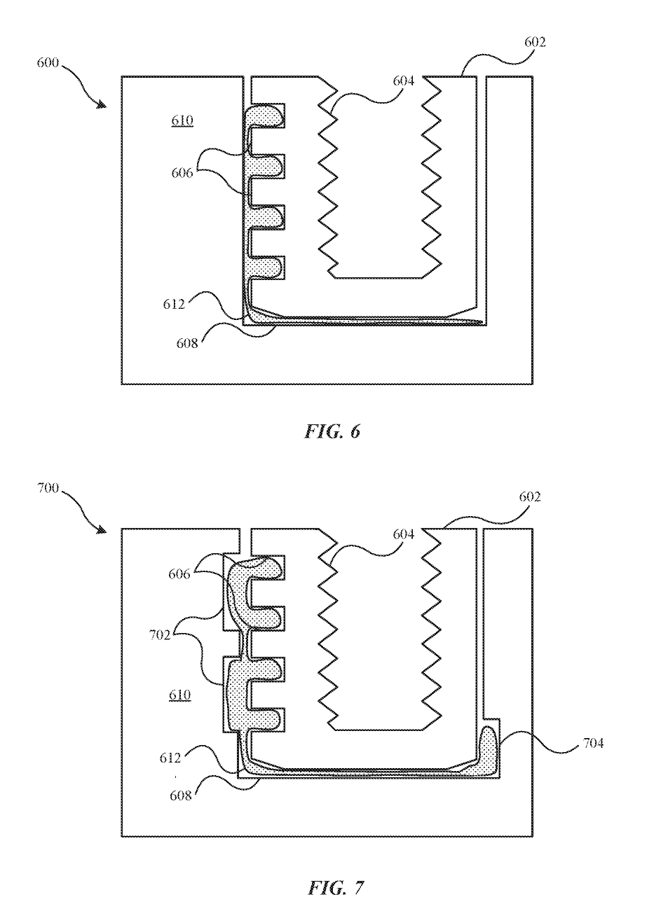

FIG. 6 illustrates a cross sectional view 600 of an insert nut 602 disposed within a cavity 608 of a portion of a housing 610. The housing 610 can be any housing suitable for containing components for a computing device. The housing 610 can be made from any material including, but not limited to, metal, ceramic, plastic, or any other material suitable for use in a device housing. Initially, the cavity 608 of the housing 610 can include some amount of adhesive 612 that will flow over the side of the insert nut 602 when the insert nut 602 is pressed into the cavity 608 and against the adhesive 612. The adhesive 612 can flow along the side of the of the insert nut 602 and between the ribs 606. The amount of surface area of the insert nut 602 over which the adhesive 612 will be disposed can be to promote the flow of adhesive 612 between the ribs 606. Once the adhesive 612 has been forced between the ribs 606, the adhesive 612 can undergo at least a partial curing to secure the insert nut 602 in place within the cavity 608.

FIG. 7 illustrates a cross sectional view 700 of an insert nut 602 disposed within a cavity 608 that has been cut to include areas for receiving adhesive. The cavity 608 can include one or more cutout regions such as cutout regions 702 and cutout region 704. When the insert nut 602 is pressed into the cavity 608 and an adhesive 612 disposed within the cavity 608, the adhesive 612 can flow between the ribs 606 of the insert nut 602 and into the cutout regions 702 and 704. In this way, more adhesive 612 will effectively bond the insert nut 602 and the housing 610, thereby creating a more secured and reliable connection for the insert nut 602. The cutout regions 702 and 704 can be subcavities of the cavity 608 and therefore increase the amount of volume of the cavity 608. The cutout regions 702 and 704 can be included on at least a portion of the internal walls of the cavity 608. In some embodiments, multiple cutout regions 702 and 704 are included at different locations of the internal wall of the cavity 608.

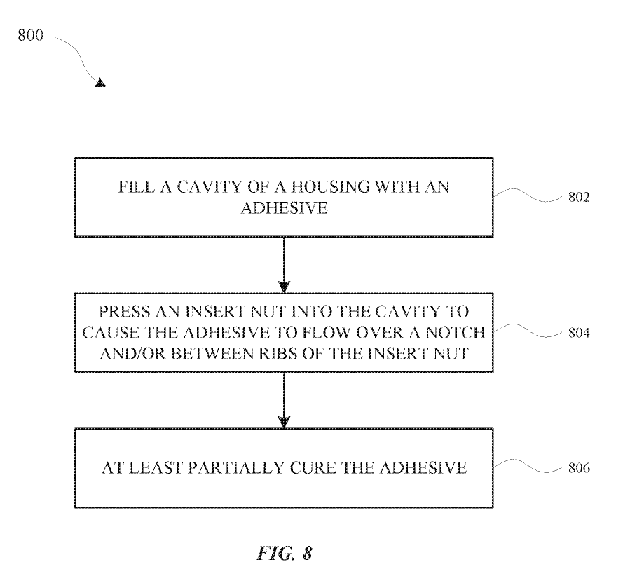

FIG. 8 illustrates a method 800 for attaching an insert nut, as described herein, to a housing for a computing device. The method 800 can be performed by a computer, a control circuit, or any other device suitable for assisting in assembling part of a computing device. The method 800 can include a step 802 of filling a cavity of a housing with an adhesive. The adhesive can be a curable adhesive that solidifies when the temperature of the adhesive is changed. However, the adhesive can also be any other type of adhesive, such as an ultra violet light curable adhesive, suitable for attaching parts to a device housing. The method 800 can also include a step 804 of pressing the insert nut into the cavity to cause the adhesive to flow over a notch and/or between ribs of the insert nut. The volume and viscosity of the adhesive can be adjusted to improve the flow of the adhesive between the ribs and over the notches in the ribs. Additionally, by optimizing the volume and viscosity of the adhesive, more contact between the cavity walls, the adhesive, and the insert nut can be realized. The method 800 can further include a step 806 of at least partially curing the adhesive. Curing the adhesive can include changing the temperature of the adhesive, using ultra violet light to cure the adhesive, or any other process for curing adhesive.

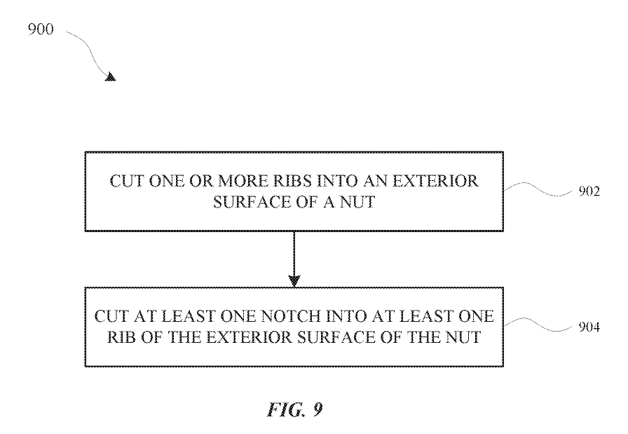

FIG. 9 illustrates a method 900 for manufacturing the insert nut discussed herein. The method 900 can be performed by any apparatus suitable for assisting in manufacturing a device component. The method 900 can include a step 902 of cutting one or more ribs into an exterior surface of a nut. The method 900 can further include a step 904 of cutting at least one notch into at least one rib of the exterior surface of the nut. The areas between each rib can be arranged for an adhesive to flow over, and the notches can act as passage ways for the adhesive to flow between ribs. In this way, when the insert nut is pressed into a cavity that has adhesive, the adhesive will flow over the notches and between multiple ribs in order to create a sufficient bond between the cavity and the insert nut.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A method for attaching a nut to a housing of a computing device, the nut comprising a ribbed exterior with at least one notch and a threaded interior, and the method including steps of:
depositing an adhesive into a cavity of the housing; and
depressing the nut into the cavity of the housing such that the adhesive flows over the at least one notch.

2. The method of claim 1, further comprising:
causing the adhesive to move over the at least one notch and between ribs of the threaded exterior to create a bond between the nut and the housing.

3. The method of claim 1, further comprising:
at least partially curing the adhesive after depressing the nut into the cavity of the housing.

4. The method of claim 1, wherein the housing is made from a ceramic material.

5. The method of claim 1, wherein depositing the adhesive includes providing an amount of adhesive sufficient to move between each rib of the ribbed exterior.

6. An insert nut, comprising:
a body having a threaded interior and a ribbed exterior, the ribbed exterior comprising ribs and at least one notch, wherein the at least one notch is configured to act as a fluid pathway between the ribs.

7. The insert nut of claim 6, wherein the ribbed exterior includes multiple notches that are staggered about a periphery the ribbed exterior.

8. The insert nut of claim 6, wherein the ribbed exterior includes multiple notches that at least partially overlap relative to a longitudinal axis of the body.

9. The insert nut of claim 6, wherein the ribs include an end rib extending from the body further than a rib that is adjacent to the end rib.

10. A computing device, comprising:
a housing that includes at least one side wall having a cavity;
an insert nut disposed within the cavity, the insert nut comprising a threaded interior and a ribbed exterior, the ribbed exterior comprising at least one notch in a rib of the ribbed exterior; and
an adhesive disposed between the at least one notch and a wall of the cavity.

11. The computing device of claim 10, wherein the housing is made from a ceramic material.

12. The computing device of claim 10, wherein a perimeter of the insert nut includes a straight portion and a curved portion.

13. The computing device of claim 10, further comprising:
an electrical component; and
a screw fastened to the insert nut through a portion of the electrical component to secure the electrical component to the housing.

14. The computing device of claim 13, wherein the electrical component is a microphone, a speaker, a vibrator, or a receptacle.

15. The computing device of claim 13, wherein the housing includes a depressed region having a perimeter wall disposed between the insert nut and the depressed region.

16. The computing device of claim 10, wherein the adhesive is disposed between at least two ribs of the ribbed exterior.

17. The computing device of claim 10, wherein the ribbed exterior includes a plurality of staggered notches.

18. The computing device of claim 10, wherein the adhesive is a cured adhesive.

19. The computing device of claim 10, wherein the wall of the cavity includes a subcavity and a portion of the adhesive is disposed within the subcavity.

20. The computing device of claim 10, wherein the ribbed exterior includes an end rib extending away from the threaded interior further than a rib that is adjacent to the end rib.
